(19) United States
(12) Patent Application Publication
(10) Pub. No.: US 2010/0079065 A1
(43) Pub. Date: Apr. 1, 2010

(54) DISPLAY DEVICE

(75) Inventor: Norihiko KAMIURA, Ishikawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Toshiba Mobile Display Co., Ltd., Tokyo (JP)

(21) Appl. No.: 12/489,499

(22) Filed: Jun. 23, 2009

(30) Foreign Application Priority Data
Sep. 26, 2008 (JP) 2008-249009

(51) Int. Cl. H01L 51/54

(52) U.S. Cl. 313/504

(57) ABSTRACT

A display device including an active area having a plurality of pixels and a peripheral area outside the active area comprises an array substrate including a plurality of transistors corresponding to said pixels each other, an organic insulation film covering said transistors in said active area and a plurality of display elements each of which includes a first electrode, a second electrode and an organic active layer therebetween over said organic insulation film; a sealing substrate disposed to be opposed to said array substrate; a seal member made of frit glass and disposed between said array substrate and said sealing substrate at a seal area in said peripheral area; wherein said organic insulation film is removed at said seal area, said array substrate includes a laminate structure of metal layer and an inorganic non-metal layer on said metal layer at said seal area and said seal member directly contacts to said inorganic non-metal layer.

### CROSS-REFERENCE TO RELATED APPLICATIONS

This application is based upon and claims the benefit of priority from prior Japanese Patent Application No. 2008-249009, filed Sep. 26, 2008, the entire contents of which are incorporated herein by reference.

### BACKGROUND OF THE INVENTION

1. Field of the Invention

The present invention relates generally to a display device, and more particularly to a display device including a self-luminous display element.

2. Description of the Related Art

In recent years, attention has been paid to an organic electroluminescence (EL) display device as a flat-panel display device. Since the organic EL display device includes self self-luminous display elements, the organic EL display device has such features that the viewing angle is wide, no backlight is needed and thus reduction in thickness and weight can be achieved, power consumption can be decreased, and high responsivity is obtained.

By virtue of these features, attention has been paid to the organic EL display device as a promising candidate for the next-generation flat-panel display device that is to replace the liquid crystal display devices.

The organic EL display device includes an organic EL element in which an organic active layer having a light emission function is held between an anode and a cathode. The organic EL display devices are classified into a bottom emission type in which EL light that is generated from the organic EL element is extracted to the outside from an array substrate side, and a top emission type in which EL light that is generated from the organic EL element is extracted to the outside from a sealing substrate side. The organic EL element having this structure includes a thin film which easily deteriorates due to the effect of moisture or oxygen. Therefore, the EL element is needed to be sealed so as not to be exposed to the atmosphere.

There has been proposed a structure wherein a array substrate including the organic EL element and a sealing substrate are bonded each other via a sealant made of frit glass which is disposed at the peripheral area of these substrates. With this structure, the moisture is blocked to enter into the gap between the array substrate and the sealing substrate(see, e.g. Jpn. Pat. Appln. KOKAI Publication No. 2007-200840).

And there has been proposed a structure of the frit glass wherein the frit glass layer includes a first frit layer made of transparent material and a second frit layer made of non-transparent material. With this structure, it is possible to adjust the thickness of the organic EL display device (see, e.g. Jpn. Pat. Appln. KOKAI Publication No. 2007-200836).

In case of bonding the array substrate and the sealing substrate via frit glass, the following steps are necessary to seal the organic EL display device, generally.

Firstly, frit glass is disposed on the peripheral area of the sealing substrate. Next, it is heated for hardening. Secondly, after cooling the frit glass, the array substrate is attached on the sealing substrate via the frit glass. And then, the frit glass is irradiated with a laser so as to melt and harden it. Thus, the organic EL element is sealed between the array substrate and the sealing substrate.

By the way, in the flat-panel display device field, including organic EL display device field, there is a requirement to make overall size of the device smaller with keeping an active area size. In other words, reducing the picture-frame size of the device is desired. Therefore, it is desired to narrow the application width of the frit glass. On the other hand, mechanical strength and sealing performance of the device have to be maintained.

However, in the portion where the frit glass is in directly contact on a metal line on the array substrate, the mechanical strength and the sealing performance are weaker against the outer shock than in other portion.

### BRIEF SUMMARY OF THE INVENTION

The present invention has been made in consideration of the above-described problems, and the object of the invention is to provide a display device wherein the mechanical strength and the sealing performance can be increased and the picture-frame size can be reduced.

According to a first aspect of the present invention, there is provided a display device including an active area having a plurality of pixels and a peripheral area outside the active area comprising: an array substrate including a plurality of transistors corresponding to said pixels each other, an organic insulation film covering said transistors in said active area and a plurality of display elements each of which includes a first electrode, a second electrode and an organic active layer therebetween over said organic insulation film; a sealing substrate disposed to be opposed to said array substrate; a seal member made of frit glass and disposed between said the array substrate and said sealing substrate at a seal area in said peripheral area; wherein said organic insulation film is removed at said seal area, said array substrate includes a laminate structure of metal layer and an inorganic non-metal layer on said metal layer at said seal area and said seal member directly contacts to said inorganic non-metal layer.

The present invention can provide a display device, wherein the mechanical strength and the sealing performance can be increase and the picture-frame size can be reduced. Moreover, the production yield for the display device does not decrease. Additionally, because the display element is not exposed to the atmosphere and the deterioration of the display element is restrained, a good display quality can be achieved and the lifetime can be increased.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 schematically shows the structure of an organic EL display device according to an embodiment of the present invention;

FIG. 2 is a cross-sectional view that schematically shows a cross-sectional structure of the organic EL display device show in FIG. 1;

FIG. 3 is a plan view that schematically shows a positional relationship between a seal member and a metal layer which is provided under the seal member according to the embodiment of the present invention;

FIG. 4 is a cross-sectional view that schematically shows a structure which includes a laminate structure of a metal layer and a metal oxide layer on the metal layer.

FIG. 5A to 5D are plan views of other examples according to the present invention.

### DETAILED DESCRIPTION OF THE INVENTION

A display device according to an embodiment of the present invention will now be described with reference to the accompanying drawings. In this embodiment, a self-luminous display device, such as an organic EL (electroluminescence) display device, is described as an example of the display device.

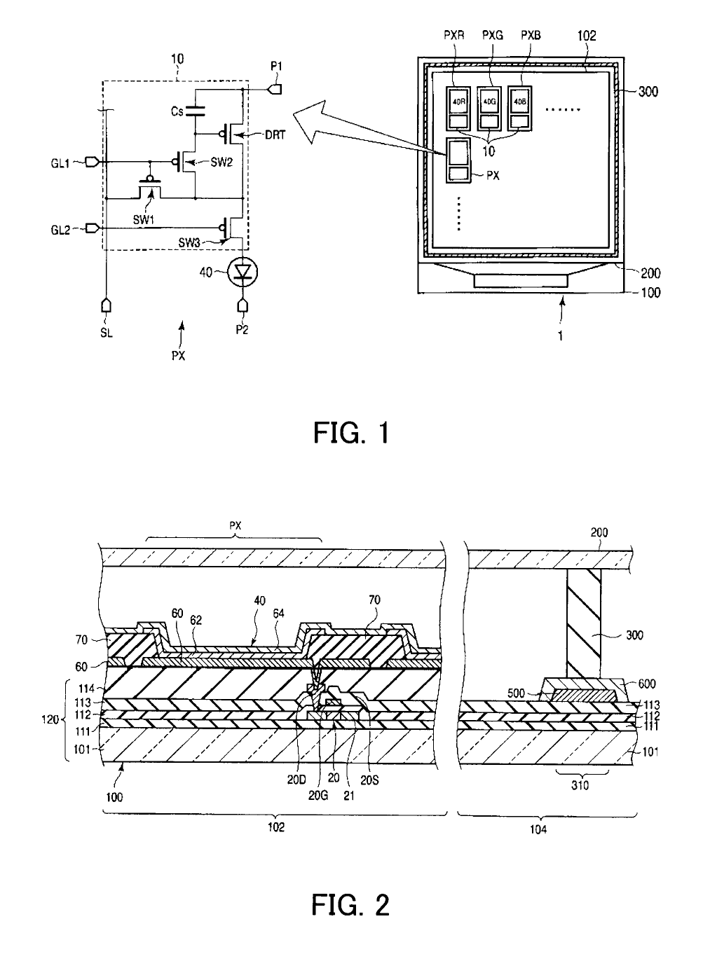

As is shown in FIG. 1, an organic EL display device 1 includes an array substrate 100 with an active area 102 for displaying an image. The active area 102 is composed of a plurality of pixels PX which arrayed in a matrix. FIG. 1 shows the organic EL display device 1 of a color display type, by way of example, and the active area 102 is composed of a plurality of kinds of color pixels, for instance, a red pixel PXR, a green pixel PXG and a blue pixel PXB corresponding to the three primary colors.

At least the active area 102 of the array substrate 100 is sealed by a sealing substrate 200. The sealing substrate 200 is made of a transparent and an insulating material (especially glass). Inner surface of the sealing substrate 200 which is opposed to the array substrate 100 may be flat or may have a recess portion corresponding to at least the active area 102. The thickness of the recess portion is smaller than one of the peripheral area.

The array substrate 100 and the sealing substrate 200 are bonded each other via a seal member 300 which is a frame shape and is disposed around the active area 102. In this embodiment, the seal member 300 is made of frit glass.

Each of the pixels PX (R, G, B) includes a pixel circuit 10 and a display element 40 which is driven and controlled by the pixel circuit 10. Needless to say, the pixel circuit 10 shown in FIG. 1 is merely an example, and pixel circuits with other structures are applicable. In the example shown in FIG. 1, the pixel circuit 10 is configured to include a driving transistor DRT, various switches (a first switch SW1, a second switch SW2 and a third switch SW3) and a storage capacitance element Cs. The driving transistor DRT has a function of controlling the amount of electric current that is supplied to the display element 40. The first switch SW1 and the second switch SW2 function as a sample/hold switch. The third switch SW3 has a function of controlling the supply of driving current from the driving transistor DRT to the display element 40, that is, the turning on/off of the display element 40. The storage capacitance Cs has a function of retaining a gate-source potential of the driving transistor DRT.

The driving transistor DRT is connected between a high-potential power supply line P1 and the third switch SW3. The display element 40 is connected between the third switch SW3 and a low-potential power supply line P2. The gate electrodes of the first switch SW1 and second switch SW2 are connected to a first gate line GL1. The gate electrode of the third switch SW3 is connected to a second gate line GL2. The source electrode of the first switch SW1 is connected to a video signal line SL. The driving transistor DRT, first switch SW1, second switch SW2 and third switch SW3 are composed of, for example, thin-film transistors, and their semiconductor layers are formed of polysilicon (polycrystalline silicon) in this example.

In the case of this circuit structure, the first switch SW1 and second switch SW2 are turned on, on the basis of the supply of an ON signal from the first gate line GL1. An electric current flows from the high-potential power supply line P1 to the driving transistor DRT in accordance with the amount of electric current flowing in the video signal line SL, and the storage capacitance element Cs is charged in accordance with the electric current flowing in the driving transistor DRT. Thereby, the driving transistor DRT can supply the same amount of electric current as the one which is supplied from the video signal line SL from the high-potential power supply line P1 to the display element 40.

On the basis of the supply of the ON signal from the second gate line GL2, the third switch SW3 is turned on, and the driving transistor DRT supplies a predetermined amount of current corresponding to a predetermined luminance from the high-potential power supply line P1 to the display element 40 via the third switch SW3 in accordance with the capacitance that is retained in the storage capacitance element Cs. Thereby, the display element 40 emits light with a predetermined luminance.

The display element 40 is composed of the organic EL element 40 (R, G, B). Specifically, the red pixel PXR includes an organic EL element 40R which mainly emits light corresponding to a red wavelength. The green pixel PXG includes an organic EL element 40G which mainly emits light corresponding to a green wavelength. The blue pixel PXB includes an organic EL element 40B which mainly emits light corresponding to a blue wavelength.

The respective kinds of organic EL elements 40 (R, G, B) have basically the same structure. For example, as shown in FIG. 2, the array substrate 100 includes a plurality of organic EL elements 40 which are disposed on the major surface side of a wiring substrate 120. The wiring substrate 120 is configured such that insulation layers, such as an under coat layer 111, a gate insulation film 112, an interlayer insulation film 113 and an organic insulation film (planarizing film) 114, and various switches SW, driving transistor DRT, storage capacitance element Cs and various wiring lines (gate lines, video signal lines, power supply lines, etc.), are provided on an insulating support substrate 101 such as a glass substrate. The under coat layer 111, gate insulation film 112 and interlayer insulation film 113 are made of inorganic materials such as silicon nitride (SiNx) and silicon oxide (SiO2).

Specifically, in the example shown in FIG. 2, a semiconductor layer 21 of some transistor elements 20 such as the switches and the driving transistor DRT is provided on the under coat layer 111. The transistor element 20 shown in FIG. 2 corresponds to the third switch SW3 in FIG. 1. The semiconductor layer 21 is covered by the gate insulation film 112.

A gate electrode 20G of the transistor element 20 and a gate line not shown are provided on the gate insulation film 112. A source electrode 20S and a drain electrode 20D of the transistor element 20 and a signal lines not shown are disposed on the interlayer insulation film 113.

These source electrode 20S and drain electrode 20D each contact to the semiconductor layer 21 via a contact hole passing through the gate insulation film 112 and the interlayer insulation film 113. These source electrode 20S, drain electrode 20D and the signal line are covered by the organic insulation film 114. This organic insulation film 114 is, for example, formed by coating resin material so as to absorb the roughness of the surface of the under layer and planarize it.

In this embodiment, the organic EL element 40 is provided on the organic insulation film 114. This organic EL element 40 has a structure including a first electrode 60, a second electrode 64 and an organic active layer 62 held therebetween. More detailed structure of the organic EL element 40 is described as follows.

Specifically, the first electrode 60 functions as an anode and is provided on the organic insulation film 114 in an insular shape in each pixel. This first electrode 60 contacts to the drain electrode 20D via a contact hole passing through the organic insulation film 114.

The first electrode 60 may be a laminated structure which includes a reflecting layer made of conductive material such as aluminum (Al) or silver (Ag) and a transparent conductive layer such as indium-tin-oxide (ITO) or indium-zinc-oxide (IZO) on the reflecting layer. The first electrode 60 may be also a single layer structure made of a reflecting layer or of a transparent conductive layer. However, in case of top-emission type, it is desirable that the first electrode 60 includes a reflecting layer.

The organic active layer 62 is disposed on the first electrode 60 and includes at least a light-emitting layer. The organic active layer 62 may include layers other than the light-emitting layer. For example, the organic active layer 62 may include a hole injection layer, a hole transporting layer, a blocking layer, an electron transporting layer, an electron injection layer and a buffer layer, or the organic active layer 62 may include a layer in which the functions of these layers are integrated. The light-emitting layer is formed of an organic material and other layers in the organic active layer 62 may be formed of an inorganic material or of an organic material. The light-emitting layer is formed of an organic compound having a light emission function of emitting red, green or blue light. At least a part of the organic active layer 62 is formed of a high polymer material, and the organic active layer 62 can be formed by coating a liquid-phase material by selective coating method such as ink jet method, and then drying the liquid-phase material. The organic active layer 62 also may include a layer made of a low polymer material. In that case, the layer like this can be formed by an evaporation coating method with using an evaporation mask.

The second electrode 64 is disposed on the all organic active layers 62 commonly, and functions as, for example, a cathode. The second electrode 64 may be a laminate structure including a semi-transmissive layer made of mixture of silver (Ag) and magnesium (Mg) and a transparent conductive layer such as indium-tin-oxide (ITO). The second electrode 64 may be also a single layer structure made of a semi-transmissive layer or of a transparent conductive layer. However, in case of top-emission type, it is desirable that the second electrode 64 includes a semi-transmissive layer.

The array substrate 100, in the active area 102, includes partition walls 70 which isolate at least the pixels PX (R, G, B) of neighboring colors. The partition walls 70 are disposed, for example, along the peripheral edges of the first electrodes 60, and are formed in lattice shapes or in stripe shapes in the active area 102. This partition walls 70 make the organic EL elements having different colors partitioned each other. The partition walls 70 are formed, for example, by patterning a resin material. The partition walls 70 are covered by the second electrode 64.

The sealing substrate 200 is disposed so as to oppose to the organic EL elements 40 in the array substrate 100. The array substrate 100 and the sealing substrate 200 are bonded each other by the seal member 300 which is disposed around the active area 102. The seal member 300 is made of frit glass. The frit glass can be melt by heat such as irradiation with a laser, and can bond the array substrate 100 and the sealing substrate 200. That makes an enclosed space between the array substrate 100 and the sealing substrate 200. The organic EL elements 40 are disposed in the enclosed space, and they are sealed.

By the way, in this embodiment, the array substrate 100 includes a laminate structure of a metal layer 500 and a metal oxide layer 600 on the metal layer as an under layer of the seal member 300. The metal layer 500 is disposed around the active area 102 and is made of metal material having light reflectivity. The metal oxide layer 600 is disposed on the metal layer 500 as an inorganic non-metal layer and is made of metal oxide material having light transparency. The seal member 300 is welded the metal oxide layer 600. In other words, the metal layer 500 and the seal member 300 are welded each other via the metal oxide layer 600.

For example, as shown in FIG. 2, the under coat layer 111, the gate insulation film 112 and the interlayer insulation film 113 are disposed at the active area 102 and are extended at outside of the active area 102 including the seal area 310. The metal layer 500 is disposed on the interlayer insulation film 113 so as to correspond to the seal area 310. The metal oxide layer 600 is laminated on the metal layer 500.

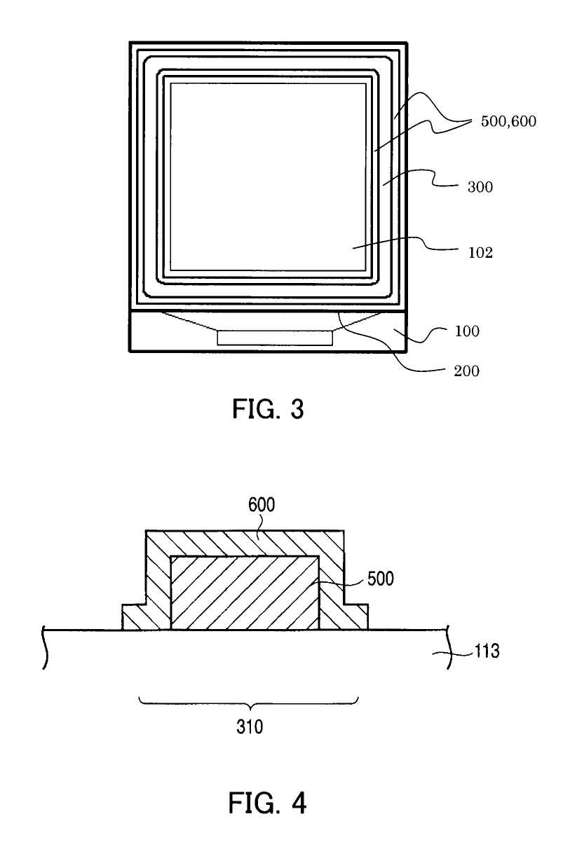

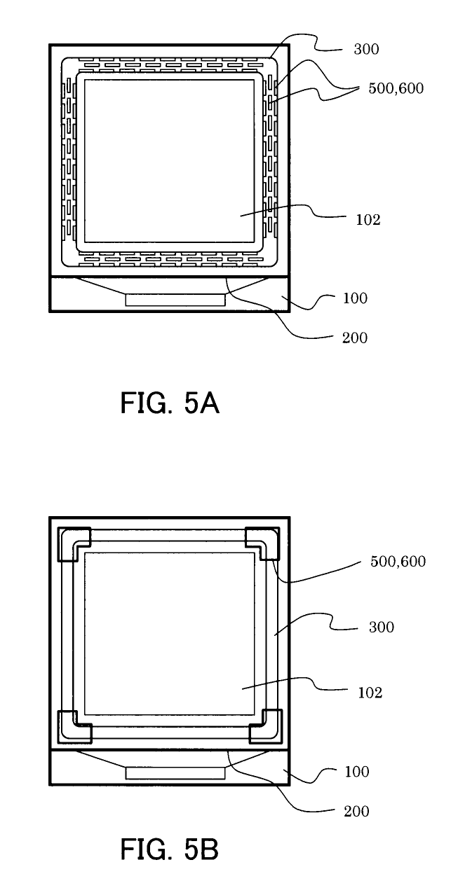

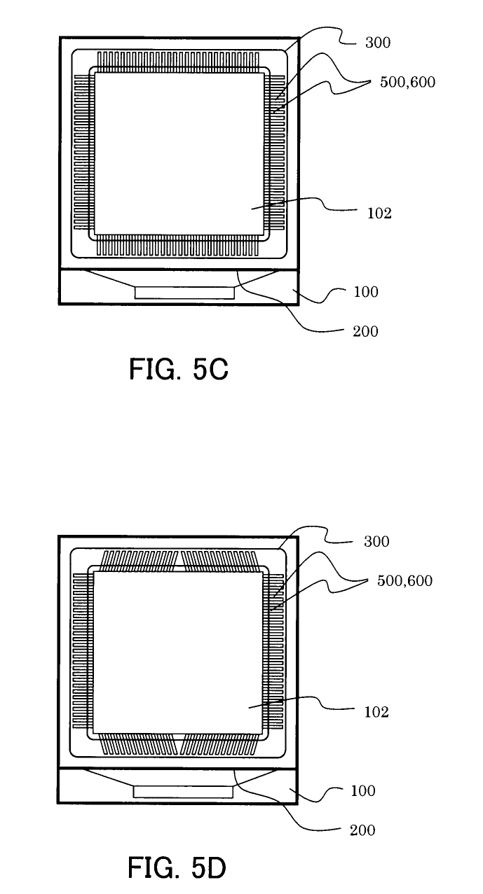

The laminate structure of the metal layer 500 and the metal oxide layer 600 is, for example as shown in FIG. 3, disposed so as to surround the active area 102 and is in a continuous frame shape. In this case, the metal oxide layer 600 is overlapped with the seal member 300 in whole circumference. The laminate structure may be a discontinuous shape. For example, the laminate structure of the metal layer 500 and the metal oxide layer 600 may be comprised in a plurality of islands which are dotted around the active area 102 as shown in FIG. 5A. Furthermore, the laminate structure may be disposed along at least one side of the active area 102 or may be only disposed at the specific portion which is needed to be strong bond such as a corner portion of the seal area 310 as shown in FIG. 5B. In addition, the laminate structure may be comprised in a plurality lines which are extended in the seal-width direction as shown in FIG. 5C. Furthermore, a part of the lines may be extended in the oblique direction as shown in FIG. 5D.

The metal oxide layer 600 as the inorganic non-metal layer is exposed at the surface of the array substrate 100 at the seal area 310. Therefore, when the sealing substrate 200 applied the seal member 300 made of frit glass is attached to the array substrate 100, the seal member 300 contacts the metal oxide layer 600 on the array substrate 100.

And by the irradiation to the seal member 300 made of frit glass with a laser light from the outside of the sealing substrate 200, the frit glass is heated. At this time, a part of the laser light passing through the metal oxide layer 600 is reflected by the surface of the metal layer 500 and go to the frit glass. That is, the temperature of the boundary face between the seal member 300 and the metal oxide layer 600 increases because of reflection by the surface of the metal layer 500. Thus, the seal member 300 made of frit glass is welded to the metal oxide layer 600.

The inorganic non-metal layer such as the metal oxide layer 600 can be bonded to frit glass more strongly than to a metal.

The metal oxide layer 600 is a competitively higher melting point than the one of metal layer 500. Therefore, the metal oxide layer 600 functions as a buffer layer between the seal member 300 and the metal layer 500, and can decrease the damage of the metal layer 500 caused by the heat in the welding process. That is, the metal oxide layer can prevent the boundary face between the metal layer 500 and the metal oxide layer 600 from peeling or a disordering of the shape.

As described above, since the metal oxide layer 600 is a light transmissive, a part of the laser light passes through the metal oxide layer 600 and reflects by the surface of the metal layer 500. In the result, the energy of the laser light can be absorbed in the frit glass efficiently. Therefore, melting of the frit glass is promoted, and the frit glass can bond the array substrate 100 and the sealing substrate 200 strongly.

Additionally, in the structure which includes the metal oxide layer 600 laminated on the metal layer 500, since it maintains high heat conductivity, it can avoid being high temperature at a local point which is irradiated with a laser light, and a heat distribution in the surface contacted to frit glass can be even. Therefore, it can bond the frit glass and the metal oxide layer 600 evenly.

Thus, since it does not to need to enlarge the seal area 310 considerably for bonding the array substrate 100 and the sealing substrate 200, it can achieve a reduction in picture frame size. Moreover, the mechanical strength and the sealing performance can be increased and the production yield for the display device does not decrease. Additionally, because the display element is not exposed to the atmosphere and the deterioration of the display element is restrained, a good display quality can be achieved and the lifetime can be increased.

If there is no metal oxide layer 600 and the frit glass contacts the metal layer 500 directly, the mechanical strength against the outer shock may be weak because of the weakness of bonding performance between frit glass and a metal.

Moreover, if there is the organic insulation film 114 under the frit glass, the mechanical strength against the outer shock may be also weak because the organic insulation film 114 under the frit glass is damaged by the irradiation with a laser which is for melting the frit glass. However, the organic insulation film 114 is more usable than inorganic film for planarizing the surface in active area 102. Therefore, in this embodiment, the organic insulation film 114 is provided in the active area 111 and is removed from at least the seal area 310.

The metal oxide layer 600 may be replaced by other inorganic material such as silicon nitride (SiN) and silicon oxide (SiO2) as the inorganic non-metal layer. In case that these material are used, it is desirable that the material is common with a film comprised in the active area 102, because it does not need to add a special manufacturing process.

A detailed constitution of the organic EL display device 1 in this embodiment will be described bellow.

The metal layer 500 is preferable to be made of at least one material among aluminum (Al), silver (Ag), aluminum-neodymium (AlNd) and aluminum alloy. The metal layer 500 can be formed, for example, by patterning a metal film into a desired pattern by a patterning method such as a photolithography method, a dry etching method or a wet etching method after the metal material is formed by a film forming method such as a magnetron sputter method.

The metal oxide layer 600 is preferable to be made of at least one material among indium-tin-oxide (ITO), indium oxide (In2O3), zinc oxide (ZnO) and titanium oxide (TiO2). The metal oxide layer 600 can be formed, for example, by patterning a film of metal oxide material into a desired pattern after the metal oxide film is formed by a film forming method such as a sputter method.

The metal oxide layer 600 is formed over the surface (including upper surface and side surface) of the metal layer 500, as shown in FIG. 4.

In case that the materials above described are selected as materials of the metal layer 500 and the metal oxide layer 600, they can be formed by a same manufacturing process as the one of some wiring lines or some layers comprised in the organic EL element 40. As shown in FIG. 2, in the structure that the metal layer 500 is provided on the interlayer insulation film 113, the metal layer 500 and the metal oxide layer 600 can be formed of the same materials as some wiring lines or some layers which are formed after the interlayer insulation film 113.

For example, in the structure that the first electrode 60 on the organic insulation film 114 includes a reflecting layer and a transparent conductive layer laminated on the reflecting layer, metal layer 500 can be formed by same manufacturing process and can be made by same material as the reflecting layer, which is made of aluminum or silver mainly, of the first electrode 60. Additionally, in case that the transparent conductive layer of the first electrode 60 is made of ITO or the like, the metal oxide layer 600 can be formed by same manufacturing process and can be made of same material as the transparent conductive layer. In the above described case, since it does not need to add any more manufacturing processes in order to form the metal layer 500 or the metal oxide layer 600, the manufacturing cost does not increase.

The metal layer 500 can be formed by same manufacturing process and can be made of same material as the signal line or the source and drain electrodes which are provided on the interlayer insulation film 113. Regarding the metal layer 500, titanium (Ti), aluminum (Al), molybdenum-tantalum (MoTa), molybdenum-tungsten (MoW), or some laminate structures such as molybdenum (Mo)/aluminum (Al)/molybdenum (Mo), chrome (Cr)/aluminum (Al)/chrome (Cr) or titanium (Ti)/aluminum (Al)/titanium (Ti) is suitable for the material of some wiring lines, the electrodes and the metal layer 500.

Next, further details of this embodiment will be described bellow.

Firstly, paste of frit glass is applied to a plain glass substrate having 0.7 mm thickness which will become the sealing substrate 200. The viscosity of the paste of frit glass is in a range of 1,000 to 50,000 cP and the application conditions are set so as to be able to apply the frit glass to the substrate in width of about 0.5 mm. The shape of frit glass applied to the substrate is disposed so as to surround a region corresponding to the active area 102 of the array substrate 100. The substrate with frit glass is heated at 300° C. or more and organic material in the paste of frit glass is burned off. This makes the frit glass harden.

On the other hand, in the manufacturing process of the array substrate 100, aluminum (Al) as metal material is formed on the organic insulation film 114 in the active area 102 and on the interlayer insulation film 113 in the peripheral area 104 by magnetron sputter method. Then, the layer of aluminum (Al) is patterned into desired pattern by using the photolithography method and dry etching method (or wet etching method). By this process, the reflecting layer of the first electrode 60 in the active area 102 and the metal layer 500, with a ring shape and width of about 0.7 mm, surrounding the active area 102 in the seal area 310 are formed.

After then, ITO is formed on the whole surface including the active area 102 and the peripheral area 104 by sputter method. And the ITO film is patterned into desired pattern. Next, the patterned ITO film is annealed at 220° C. in order to stabilize the interface of the film and to improve the light transparency. Thus, the transparent conductive layer is formed on the reflecting layer of the first electrode 60 in the active area 102 and the metal oxide layer 600 as the inorganic non-metal layer is formed on the metal layer 500 in the seal area 310.

After then, in the active area 102, the partition walls 70 which isolate a pixel PX from neighbor one are formed. Next, an organic active layer 62 is formed on the first electrode 60 and the second electrode 64 is formed over the organic active layer 62. Thus, the organic EL element 40 including the first electrode 60, the second electrode 64 and the organic active layer 62 held therebetween is completed and the array substrate 100 is also completed.

Next, the array substrate 100 and the sealing substrate 200 with hardened frit glass are arranged in parallel. And then in the seal area 310, the metal oxide layer 600 on the array substrate 100 and the frit glass on the sealing substrate 200 are touched. After that, the frit glass is melt by irradiated with a laser from out side of the sealing substrate 200, and the frit glass and the metal oxide layer 600 are welded each other. Thus, the array substrate 100 and the sealing substrate 200 are bonded at 104 a whole circumference in the peripheral area, and the organic EL elements 40 on the array substrate are sealed.

In this embodiment, the laser toward the seal area 310 passes through the metal oxide layer 600 and reflects at the surface of the metal layer 500, and the energy of the laser can be absorbed in the frit glass sufficiently. That is, a heating and a melting performances to the frit glass are promoted over the surface of the metal oxide layer 600. For this reason, the bonding strength can be improved.

The present invention is not limited directly to the above-described embodiments. In practice, the structural elements can be modified and embodied without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. A display device including an active area having a plurality of pixels and a peripheral area outside the active area comprising:
an array substrate including
a plurality of transistors corresponding to said pixels each other,
an organic insulation film covering said transistors in said active area and
a plurality of display elements each of which includes a first electrode, a second electrode and an organic active layer therebetween over said organic insulation film;
a sealing substrate disposed to be opposed to said array substrate; and
a seal member made of frit glass and disposed between said array substrate and said sealing substrate at a seal area in said peripheral area;
wherein said organic insulation film is removed at said seal area, said array substrate includes a laminate structure of metal layer and an inorganic non-metal layer on said metal layer at said seal area and said seal member directly contacts to said inorganic non-metal layer.

2. The display device according to claim 1, wherein said laminate structure is disposed along said seal area continuously.

3. The display device according to claim 1, wherein said laminate structure is disposed along said seal area discontinuously.

4. The display device according to claim 1, wherein said metal layer is made of same material as one of compositions which make up said transistor.

5. The display device according to claim 4, wherein said metal layer is made of a material selected from the group consisting of titanium (Ti), aluminum (Al), molybdenum-tantalum (MoTa), molybdenum-tungsten (MoW), molybdenum (Mo) and chrome (Cr).

6. The display device according to claim 1, wherein said first electrode includes a reflecting layer and a transparent conductive layer on said reflecting layer, and said metal layer is made of same material as said reflecting layer.

7. The display device according to claim 6, wherein said metal layer is made of a material selected from the group consisting of aluminum (Al), silver (Ag) and aluminum-neodymium (AlNd) and aluminum alloy.

8. The display device according to claim 1, wherein said first electrode includes a reflecting layer and a transparent conductive layer on said reflecting layer, and said inorganic non-metal layer is made of same material as said transparent conductive layer.

9. The display device according to claim 8, wherein said inorganic non-metal layer is made of a material selected from the group consisting of indium-tin-oxide (ITO), indium oxide (In2O3), zinc oxide (ZnO) and titanium oxide (TiO2).
